(19) United States
(12) Patent Application Publication
(10) Pub. No.: US 2018/0034115 A1
(43) Pub. Date: Feb. 1, 2018

(54) TEMPERATURE MEASURING ASSEMBLY, ELECTRICAL DEVICE ASSEMBLY, BATTERY PACK CONNECTING ASSEMBLY AND BATTERY PACK

(71) Applicant: TYCO ELECTRONICS (SHANGHAI) CO. LTD., Shanghai (CN)

(72) Inventors: Ziwei LI, Shanghai (CN); Xiao ZHOU, Shanghai (CN)

(21) Appl. No.: 15/657,656

(22) Filed: Jul. 24, 2017

(30) Foreign Application Priority Data
Jul. 29, 2016 (CN) 201620815339.1

(51) Int. Cl. H01M 10/48; G01R 31/36; G01K 7/22

(52) U.S. Cl. CPC H01M 10/486; H01M 10/482; G01K 7/22; G01R 31/3606; H01M 2220/20

(57) ABSTRACT

The present invention discloses a temperature measuring assembly, electrical device assembly, battery pack connecting assembly and battery pack. The temperature measuring assembly comprises a temperature measuring element, an output connector and a heat transfer component. The temperature measuring element is configured to measure temperature of an object to be measured and output a temperature signal, and be spaced apart from the object to be measured. The output connector is electrically connected with the temperature measuring element to receive the temperature signal. The heat transfer component is configured to be in contact with the temperature measuring element, and used for contact with the object to be measured. The temperature measuring assembly of the present invention can improve precision of measuring temperature through the fit of the temperature measuring element and the heat transfer component. The output connector can conveniently output temperature signals.

### TECHNICAL FILED

The present invention relates generally to a structure for measuring temperature, and particularly to a temperature measuring assembly, an electrical device assembly, a battery pack connecting assembly and a battery pack used in an electric vehicle.

### BACKGROUND

With wide application of new energy, electric vehicles are increasingly popular among consumers. As a power source of an electric vehicle, it is the key of vehicle safety performance that a vehicle battery pack works stably. The vehicle battery pack outputs relatively high current in work, easily causing a temperature rise. Generally, to guarantee safety running of the vehicle, the operating parameters of the vehicle battery pack need to be monitored. The temperature of a vehicle battery is a key monitoring parameter.

### SUMMARY OF THE INVENTION

One of the objectives of the present invention is to provide a temperature measuring assembly, an electrical device assembly, a battery pack connecting assembly and a vehicle battery pack with a stable connection and high response speed in temperature measurement to overcome the defects of the prior art.

To fulfill the above objective, the present invention is achieved by the following technical solutions.

The present invention provides a temperature measuring assembly. The temperature measuring assembly includes a temperature measuring element, an output connector and a heat transfer component. The temperature measuring element is used for measuring the temperature of an object to be measured and outputting a temperature signal, and is spaced apart from the object to be measured. The output connector is electrically connected with the temperature measuring element to receive the temperature signal. The heat transfer component is configured to be in contact with the temperature measuring element and used for contacting with the object to be measured.

Preferably, the heat transfer component covers and encircles the temperature measuring element.

Preferably, the heat transfer component is thermo-sensitive adhesives.

Preferably, the heat transfer component is an integrated component made by curing melt silicone.

Preferably, the temperature measuring element is a thermistor.

Preferably, the temperature measuring element is a chip resistor.

Preferably, the temperature measuring element is a negative temperature coefficient thermistor.

Preferably, the output connector is a circuit board or a flexible flat cable.

Preferably, the circuit board is a flexible circuit board.

Preferably, the output connector includes an insulating layer and an electrically conductive layer. The electrically conductive layer is arranged in the insulating layer. The temperature measuring element is electrically connected with the electrically conductive layer.

Preferably, the output connector is provided with a first surface and a second surface. The output connector is provided with a connecting through hole along the through-thickness direction. The connecting through hole communicates one side of the first surface with one side of the second surface of the output connector. The temperature measuring element is arranged on the first surface or the second surface of the output connector. The heat transfer component is configured to extend and protrude from the first surface of the output connector out of the second surface of the output connector via the connecting through hole.

Preferably, two connecting through holes are provided. The heat transfer component extends and protrudes from the first surface of the output connector out of the second surface of the output connector via the two connecting through holes, and is connected with the output connector into a whole on one side of the second surface.

Preferably, the output connector includes an insulating layer and an electrically conductive layer. The insulating layer is arranged to wrap around the electrically conductive layer. A notch or a recess is formed on the upper surface of the insulating layer. The electrically conductive layer extends to the recess or the notch. The temperature measuring element is arranged at the recess or the notch, and is electrically connected with the electrically conductive layer.

Preferably, the heat transfer component covers the temperature measuring element, and at least partially fills in the notch or the recess.

Preferably, the output connector is provided with a first surface and a second surface. The output connector is provided with a connecting through hole along the through-thickness direction. The connecting through hole communicates one side of the first surface of the output connector with one side of the second surface. The recess or the notch is communicated with the connecting through hole. The temperature measuring element is arranged on the first surface or the second surface of the output connector. The heat transfer component extends and protrudes from the first surface of the output connector out of the second surface of the output connector via the connecting through hole.

The present invention further provides an electrical device assembly. The electrical device assembly includes an object to be measured and the temperature measuring assembly as described in any of the above items. The object to be measured is arranged to be in contact with the heat transfer component, and is spaced apart from the temperature measuring element.

Preferably, the object to be measured is provided with a temperature measuring end protruding along the width direction of the output connector. The output connector is arranged to be directly opposite to the temperature measuring end.

Preferably, the output connector is provided with a connecting through hole along the through-thickness direction. The output connector is arranged between the temperature measuring element and the object to be measured. The heat transfer component achieves a heat transfer connection between the temperature measuring element and the object to be measured via the connecting through hole.

Preferably, the output connector is provided with a first surface and a second surface. The output connector is provided with a connecting through hole along the through-thickness direction. The connecting through hole communicates one side of the first surface of the output connector with one side of the second surface. The temperature measuring element is arranged on the first surface or the second surface of the output connector. The heat transfer component extends and protrudes from the first surface of the output connector out of the second surface of the output connector via the connecting through hole.

Preferably, the output connector includes an insulating layer and an electrically conductive layer; and the insulating layer is arranged to wrap around the electrically conductive layer. A recess or a notch is formed in the first surface or the second surface of the insulating layer. The electrically conductive layer extends to the recess or the notch. The temperature measuring element is arranged at the recess or the notch, and is electrically connected with the electrically conductive layer.

Preferably, two electrically conductive layers are provided; and the temperature measuring element is simultaneously electrically connected with the two electrically conductive layers.

Preferably, the heat transfer component is provided with a limiting top. The limiting top is configured to cover the temperature measuring element, and at least partially fill in the recess or the notch. The limiting top has a radial size greater than that of the connecting through hole.

Preferably, the object to be measured is provided with a holding through hole or a holding groove along the through-thickness direction. The holding through hole or the holding groove is arranged to communicate with the connecting through hole. The heat transfer component extends to fill in the holding through hole or the holding groove.

Preferably, the heat transfer component is provided with a limiting bottom. The limiting bottom extends and protrudes out of the holding through hole, and has a radial size greater than that of the holding through hole.

The present invention further provides a battery pack connecting assembly. The battery pack connecting assembly includes a support and the electrical device assembly as described in any of the above items. The object to be measured is arranged on the support. The object to be measured includes one or more bus-bars. The temperature measuring assembly includes one or more temperature measuring elements, and the temperature measuring elements are spaced apart from the bus-bars in a one-to-one correspondence manner. The output connector is electrically connected with the one or more temperature measuring elements. The heat transfer component is in contact with the bus-bars, so that the bus-bars are in heat transfer connection with the corresponding temperature measuring elements.

Preferably, the output connector includes a pair of electrically conductive layers. All the temperature measuring elements are electrically connected with the pair of electrically conductive layers.

As another embodiment, the output connector includes one or multiple pairs of electrically conductive layers. Each of the temperature measuring element is electrically connected with the pair of electrically conductive layers in a one-to-one correspondence manner.

The present invention further provides a vehicle battery pack. The vehicle battery pack includes a battery, a support and the electrical device assembly as described in any of the above items. The electrical device assembly is arranged on the support. The object to be measured is a bus-bar, and is electrically connected with an electrode of the battery.

Compared with the prior art, the temperature measuring assembly of the present invention can improve the precision of measuring temperature through the fit between the temperature measuring element and the heat transfer component. The output connector can conveniently output temperature signals. Preferably, the heat transfer component is a silicone integrated component formed by filling adhesive, thereby reduces the thermal resistance to shorten the heat conduction time, has good insulating performance, and can enable the temperature measuring element to be stably assembled into a whole.

### BRIEF DESCRIPTION OF DRAWINGS

FIG. 1 is a structural schematic diagram of a temperature measuring assembly provided by the present invention.

FIG. 2 is a structural schematic diagram of the temperature measuring assembly shown in FIG. 1 without a heat transfer component.

FIG. 3 is a schematic perspective exploded view of the temperature measuring assembly shown in FIG. 1.

FIG. 4 is a front view of the temperature measuring assembly shown in FIG. 1.

FIG. 5 is a cross-sectional view of the temperature measuring assembly shown in FIG. 4 along an A-A line.

FIG. 6 is a cross-sectional view of the temperature measuring assembly shown in FIG. 4 along a B-B line.

FIG. 7 is a structural schematic diagram of an electrical device assembly provided by the present invention.

FIG. 8 is a schematic perspective exploded view of the electrical device assembly shown in FIG. 7.

FIG. 9 is a front view of the electrical device assembly shown in FIG. 7.

FIG. 10 is a cross-sectional view of the electrical device assembly shown in FIG. 7 along a C-C line.

FIG. 11 is a cross-sectional view of the electrical device assembly shown in FIG. 7 along a D-D line.

### DETAILED DESCRIPTION OF EMBODIMENTS

The present invention will be described in detail below with reference to the accompanying drawings.

### Embodiment 1

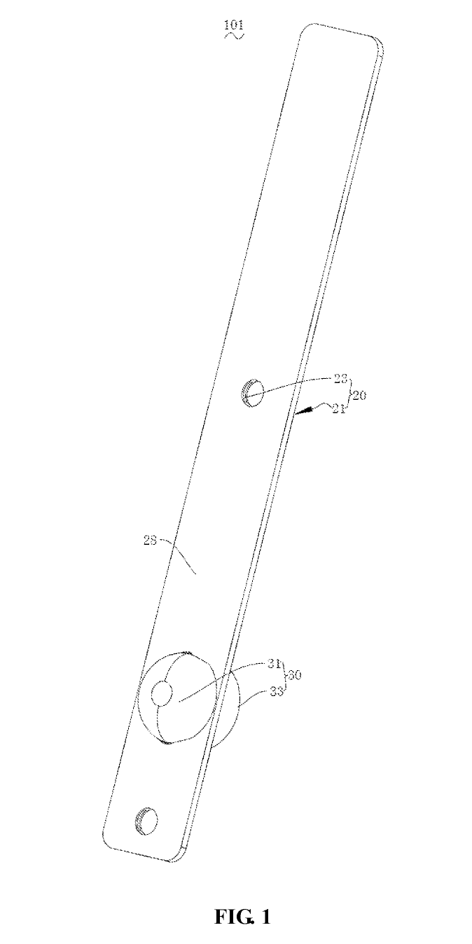

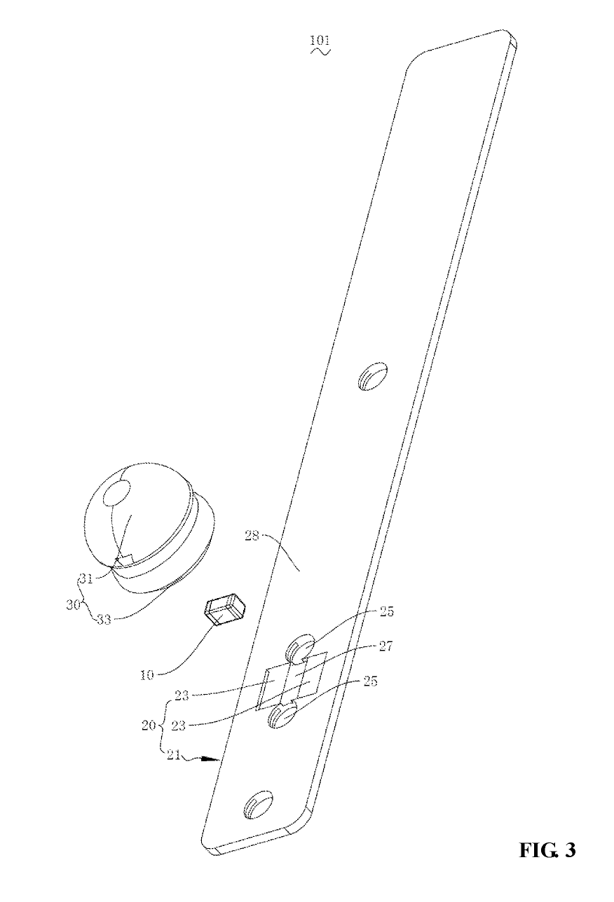

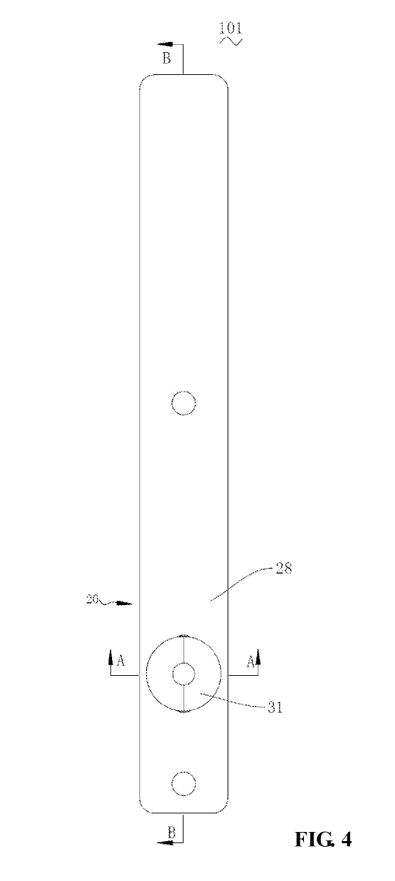

Referring to FIGS. 1-4, the present invention provides a temperature measuring assembly 101. The temperature measuring assembly 101 includes a temperature measuring element 10, an output connector 20 and a heat transfer component 30. The temperature measuring element 10 is insulated from an object to be measured 50 described below via the heat transfer component 30. The output connector 20 is electrically connected with the temperature measuring element 10. The heat transfer component 30 is insulated from the temperature measuring element 10 and the object to be measured 50 respectively.

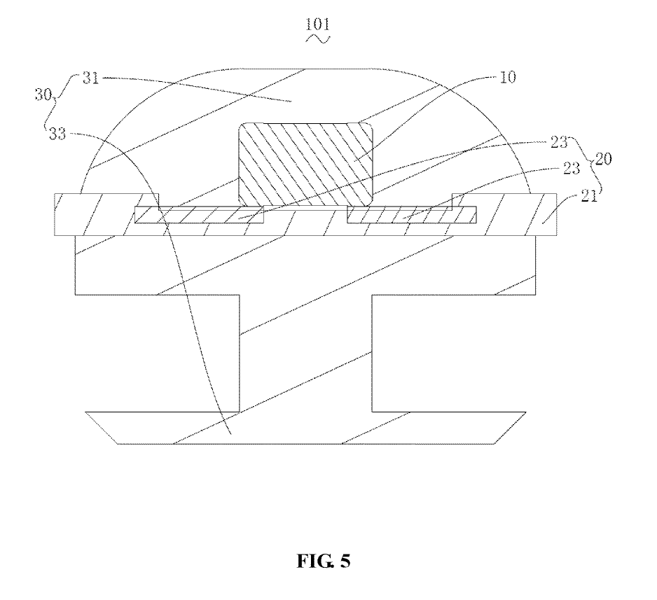

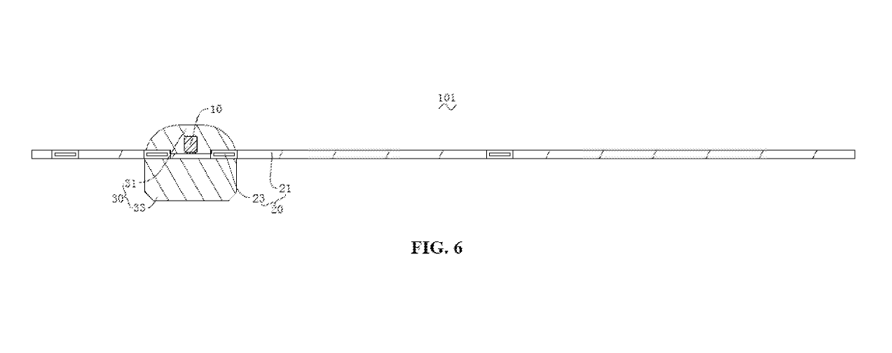

Further referring to FIGS. 5 and 6, the temperature measuring element 10 is used for directly measuring the temperature of the heat transfer component 30, to indirectly obtain the temperature of the object to be measured 50. The temperature measuring element 10 is electrically connected with the output connector 20, and outputs a temperature signal to the output connector 20. The temperature measuring element 10 may be a thermo-sensitive element, which can convert the detected temperature into a corresponding temperature signal to output. In this embodiment, to facilitate transmission of the temperature signal, the temperature measuring element 10 is a thermistor, which in turn converts the measured temperature into an electrical signal. To efficiently achieve a stable connection between the temperature measuring element 10 and the output connector 20, the temperature measuring element 10 is a chip resistor. The temperature measuring element 10 is electrically connected with the output connector 20 by wave soldering. To improve the measurement precision, the temperature measuring element 10 is a negative temperature coefficient (abbreviated as NTC) thermistor. The specific parameters and specification of the temperature measuring element 10 are selected as needed. In this embodiment, to more stably connect with the heat transfer component 30 and shorten the duration for measuring temperature, the temperature measuring element 10 is arranged in the following recess 27 of the output connector 20.

To form a stable connection, the temperature measuring element 10 is configured to span over the following two separately arranged electrically conductive layers 23. The specific position of the temperature measuring element 10 on the output connector 20 may be suitable as long as the temperature measuring element 10 can be spaced apart from the object to be measured 50 described below via the heat transfer component 30 and achieve a heat transfer connection via the heat transfer component 30. In this embodiment, the temperature measuring element 10 is arranged in the recess 27 disposed on the following upper surface 28 of the output connector 20 to be located on a different side of the output connector 20 from the object to be measured 50 described below. For example, the temperature measuring element 10 may also be arranged on the lower surface of the output connector 20, and even extend into a holding hole 53 of the following object to be measured 50 to be directly opposite to the object to be measured.

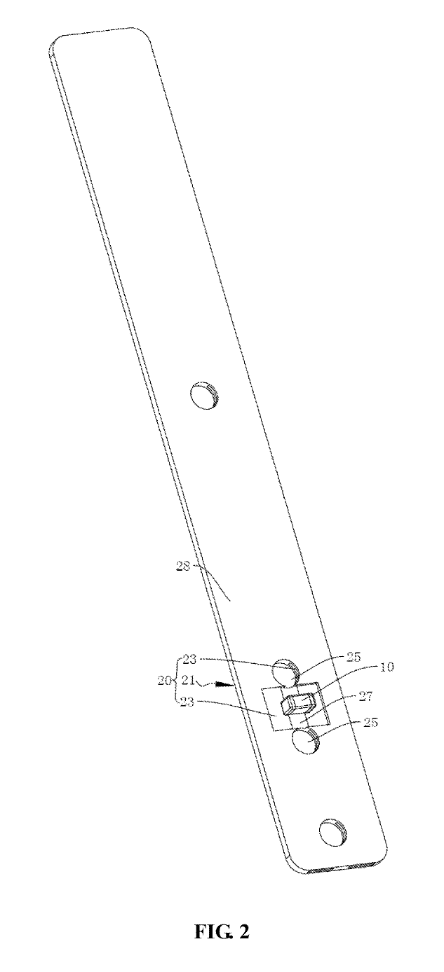

Referring to FIGS. 2, 3, 5 and 6, the output connector 20 is electrically connected with the temperature measuring element 10 to receive the temperature signal. According to different connecting requirements, the output connector 20 may adopt different conductor materials, specifications and shapes. The shape of the output connector 20 is selected according to needs. In this embodiment, the output connector 20 is roughly strip-shaped or lath-shaped. To facilitate convenient and stable transmission of electrical signals and current, the output connector 20 may be a circuit board. The circuit board is also called a printed circuited board (abbreviated as PCB). The circuit board is used for transmitting the temperature signal and electrical signals or current in other forms. To conveniently obtain bending performance beneficial to a narrow installation space, the circuit board 40 may be an FBC (Flexible Printed Circuited Board). In this embodiment, the output connector 20 is a flexible flat cable (abbreviated as FFC) to achieve better bending performance for universal installation and cost reduction.

To achieve stable and safe connecting performance, the output connector 20 includes an insulating layer 21 and an electrically conductive layer 23. The output connector 20 is provided with a first surface 28 and a second surface (not shown in the figures). The first surface 28 and the second surface are arranged back to back. A connecting through hole 25 described below is formed along the thickness direction of the output connector 20, and correspondingly, the connecting through hole 25 communicates one side of the first surface 28 of the output connector 20 with one side of the second surface. The insulating layer 21 may be in the shape of a lath made of any insulating material. In this embodiment, the insulating layer 21 is made of PET (Polyethylene glycol Terephthalate) materials. To further improve the insulating performance between the object to be measured 50, the insulating layer 21 is arranged to be directly opposite to the object to be measured 50. Specifically, the lower surface of the insulating layer 21 is arranged to be directly opposite to the object to be measured 50, and the upper surface of the insulating layer 21 is configured to support the electrically conductive layer 23. The electrically conductive layer 23 is spread on the insulating layer 21 to achieve electrical conduction.

The electrically conductive layer may be made of any electrically conductive material. In this embodiment, the insulating layer 21 is a tinned flat copper wire. The number of the electrically conductive layer 23 is selected according to needs. In this embodiment, two electrically conductive layers 23 are provided. The two electrically conductive layers 23 are arranged separately and parallelly. It should be noted that the insulating layer 21 wraps around the electrically conductive layers 23, and consequently the upper surface of the output connector 20 is also the upper surface of the insulating layer 21. Moreover, to facilitate understanding, the first surface 28 shown in the figures is the upper surface of the output connector 20 (or the insulating layer 21), the second surface is the lower surface of the output connector 20 (or the insulating layer 21). The terms of “upper”, “lower” and the like in the present invention are relative concepts, and are merely used for describing the relative positions of components with reference to the accompanying drawings, rather than limiting the specific protection scopes thereof.

To enlarge the area of contact with the heat transfer component 30, the output connector 20 is provided with a connecting through hole 25 along the through-thickness direction. That is, the connecting through hole 25 runs through the upper surface of the output connector 20 to the lower surface. The connecting through hole 25 is provided for the heat transfer component 30 to extend from the temperature measuring element 10 located on the upper surface of the output connector 20 to the lower surface of the output connector 20, up to the holding hole 53 of the object to be measured 50 described below. The number, diameter and position of the connecting through hole 25 are selected according to needs. In this embodiment, two connecting through holes 25 are provided to achieve the stable holding performance of the heat transfer component 30. The two connecting through holes 25 are arranged in sequence in the length direction of the output connector 20, and are respectively located on two sides of the temperature measuring element 10. In this embodiment, the connecting through holes 25 run through the insulating layer 21, and partially through the two electrically conductive layers 23 in an equal area manner.

To strengthen the holding performance of the heat transfer component 30, the upper surface of the output connector 20 is provided with a recess 27. The recess 27 is configured to accommodate the temperature measuring element 10. After accommodating the temperature measuring element 10, the recess 27 is configured to accommodate part of the heat transfer component 30. Preferably, the recess 27 is connected with the connecting through holes 25 to enable the heat transfer component 30 to stably fill in. The recess 27 has a cross-sectional area greater than that of the temperature measuring element 10, thus having a space for accommodating part of the heat transfer component 30. The specific shape and size of the recess 27 are suitable as long as it can meet the requirement for accommodating part of the heat transfer component 30. In this embodiment, the recess 27 is a cubic groove roughly the same as the temperature measuring element 10. In this embodiment, the recess 27 is respectively formed on the upper surfaces of the two electrically conductive layers 23. As an alternative embodiment, the recess 27 may be replaced by a groove or notch.

Referring to FIGS. 1 and 3-6, the heat transfer component 30 is used for heat transfer contact with the object to be measured 50. It is conceivable that when thermal equilibrium is achieved, the heat transfer component 30 has the same temperature as the object to be measured 50 so that the temperature measuring element 10 indirectly measures the temperature of the object to be measured 50 by directly measuring the temperature of the heat transfer component 30. The shape and structure of the heat transfer component 30 are suitable, as long as heat transfer can be achieved and the temperature measuring element 10 is spaced apart from the object to be measured 50. To improve the measurement precision, the heat transfer component 30 is made of an insulating material. The heat transfer component 30 is respectively insulated from and in heat transfer contact with the temperature measuring element 10 and the object to be measured 50. The heat transfer component 30 may be made of any insulating and heat-conductive material. In this embodiment, the heat transfer component 30 is made of thermo-sensitive adhesives to achieve better heat conductivity. Further, the heat transfer component 30 is a silicone integrated component. Specifically, the heat transfer component 30 is an integrated component by curing melt silicone. In this embodiment, the heat transfer component 30 wraps around the temperature measuring element 10 in sequence via the melt silicone, fills the recess 27 on the upper surface of the output connector 20 and the connecting through holes 25 of the output connector 20, extends to fill a gap between the lower surface of the output connector 20 and the object to be measured 50, enters the following holding through hole 53 of the object to be measured 50, and finally extends to the bottom having a radial size greater than that of the holding through hole 53.

It is conceivable that the heat transfer component 30 can achieve a holding effect by filling the above spaces. In this embodiment, the heat transfer component 30 is provided with a limiting top 31 and a limiting bottom 33 to improve the holding performance. The limiting top 31 is in block fitting with the upper surface of the output connector 20. Specifically, the limiting top 31 has a radial size greater than those of the connecting through holes 25 and/or the recess 27, and thus is in block fitting with the upper surface of the output connector 20. That is, the limiting top 31 is suitable as long as it does not simultaneously drop from the connecting through holes 25 and the recess 27. To achieve more stable limiting performance, in this embodiment, the heat transfer component 30 extends in the radial direction and simultaneously covers the connecting through holes 25 and the recess 27. That is, in the manufacturing process, the melt silicone flows also to the upper surface of the output connector 20 and additionally to the connecting through holes 25 and the recess 27. Preferably, to strengthen the stability of the temperature measuring element 10 held on the output connector 20 by the heat transfer component 30, the heat transfer component 30 extends and protrudes from the first surface of the output connector 20 out of the second surface of the output connector 20 via the two connecting through holes 25, and is connected with the output connector into a whole on one side of the second surface.

### Embodiment 2

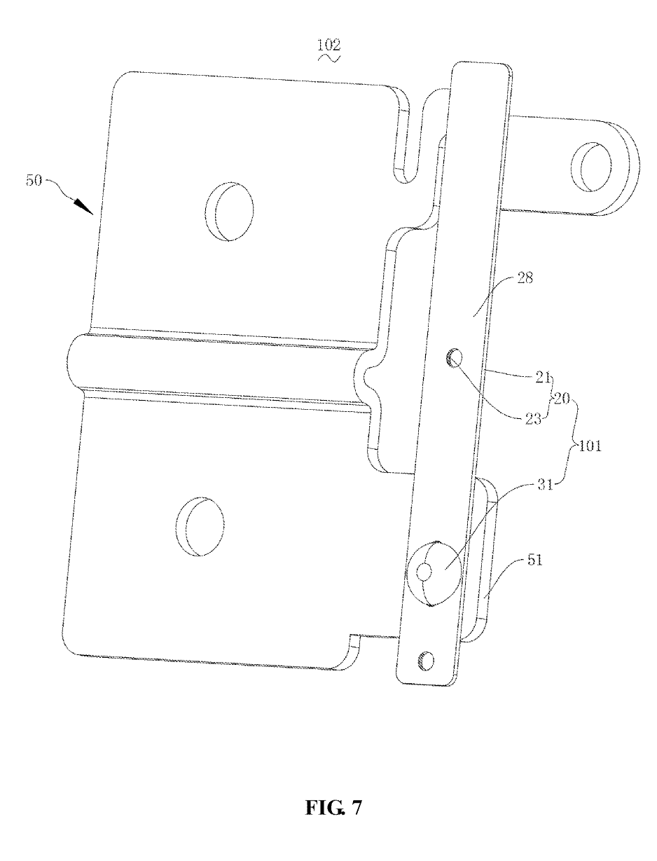

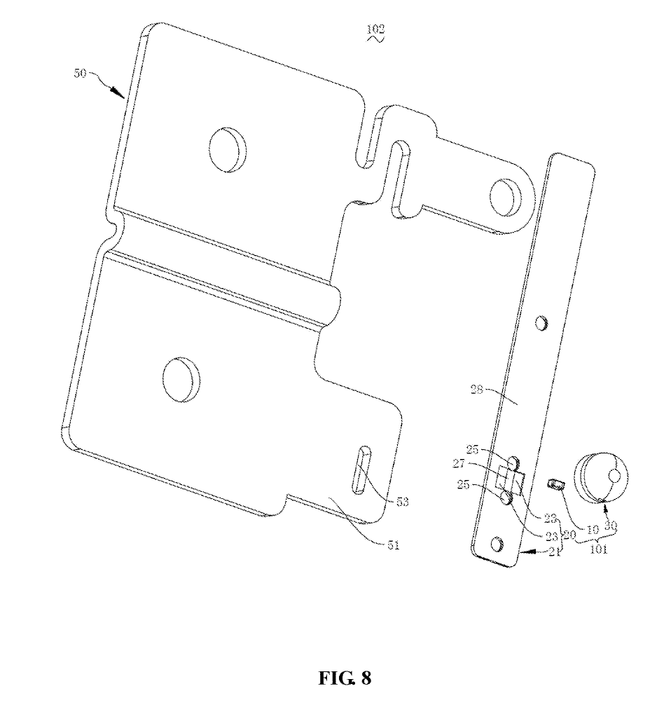

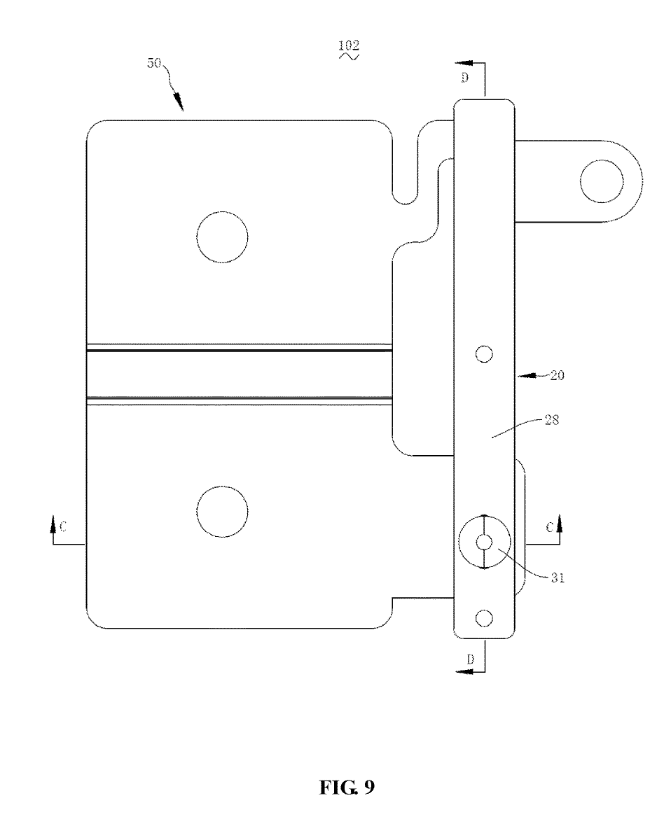

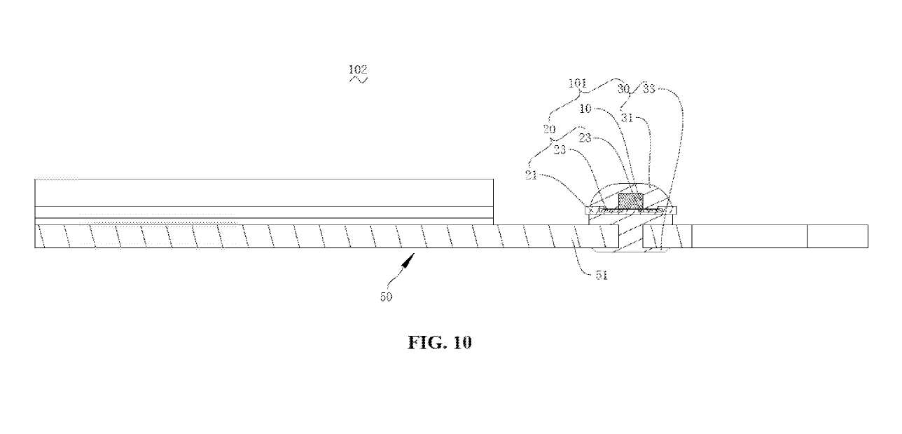

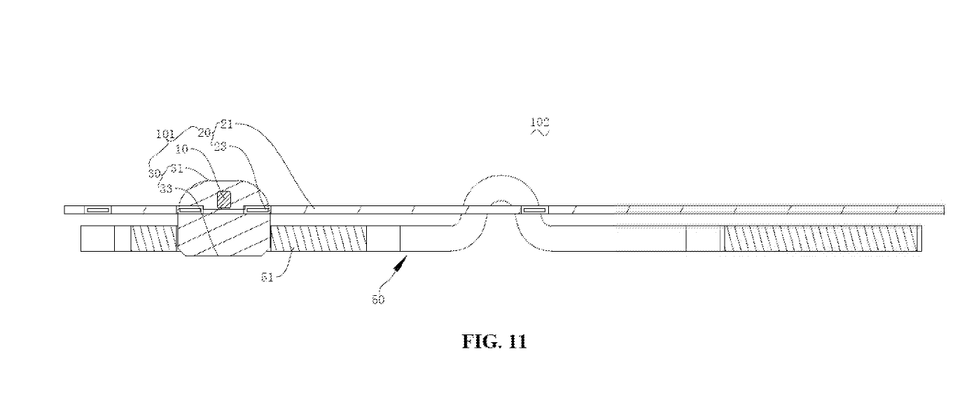

Referring to FIGS. 7-11, the present invention provides an electrical device assembly 102. The electrical device assembly 102 includes an object to be measured 50 and the temperature measuring assembly 101 described in Embodiment 1. The object to be measured 50 is in heat transfer contact with the heat transfer component 30.

The object to be measured 50 is selected according to application needs. The object to be measured 50 may be an electronic product. In this embodiment, the object to be measured 50 is a bus-bar. The bus-bar can transmit relatively high current, and thus generate a relatively large amount of heat. In this embodiment, the bus-bar is used for connecting a battery of a battery pack in a vehicle. The specific specification and parameters of the bus-bar are selected according to application needs. To sufficiently save the installation space and reduce the thermal resistance to improve the temperature measurement precision and speed, the upper surface of the object to be measured 50 is arranged to be in contact with the lower surface of the output connector 20.

To facilitate integrated assembly, in this embodiment, the object to be measured 50 is provided with a temperature measuring end 51 protruding along the width direction of the output connector 20. The upper surface of the temperature measuring end 51 is arranged to be directly opposite to the lower surface of the output connector 20. The shape and size of the temperature measuring end 51 are selected according to needs. In this embodiment, the temperature measuring end 51 is roughly in the shape of a rectangular flat plate.

To further strengthen the holding assembly performance with the heat transfer component 30, the output connector 20 is provided with a holding hole 53 on the temperature measuring end 51. The holding hole 53 is provided so that the heat transfer component 30 extends to the lower surface of the object to be measured 50. The specific diameter and specific position of the holding hole 53 are suitable as long as it can communicate with the connecting through holes 25 on the output connector 20 to facilitate circulation of the melt silicone. To facilitate quick circulation, the holding hole 53 is arranged to be directly opposite to the connecting through holes 25 of the output connector 20. In this embodiment, the holding hole 53 is roughly an elliptical hole, and is thus directly opposite to both of the two connecting through holes 25. The holding hole 53 may be a blind hole formed from the upper surface of the temperature measuring end 51, namely groove-shaped. In this embodiment, the holding hole 53 is a through hole from the upper surface of the temperature measuring end 51 through to the lower surface to further strengthen the holding performance of the heat transfer component 30.

In this embodiment, the object to be measured 50 is used for connecting a battery described below. To improve the speed of measuring temperature, the object to be measured 50 is connected with an electrode of the battery.

### Embodiment 3

The present invention further provides a vehicle battery pack (not shown in the figures). The vehicle battery pack is configured to provide power for an electric vehicle. The vehicle battery pack includes a battery (not shown in the figures) and the electrical device assembly 102 described in Embodiment 2.

The battery is electrically connected with the object to be measured 50. The signal and category of the battery are selected according to application requirements. In this embodiment, the electrode of the battery is connected with the object to be measured 50 by welding. Specifically, the electrode of the battery extends into a welding through hole of the object to be measured 50, and then the battery is connected with the object to be measured 50 by welding.

It should be noted that the terms of “upper” and “lower” in the present invention are relative concepts, and are merely used for facilitating description and understanding, rather than limiting the protection scope. Specifically, the vehicle battery pack includes the limiting top 31 of the heat transfer component 30, the electrically conductive layer 23 of the output connector 20, the insulating layer 21, the temperature measuring end 51, the limiting bottom 33 of the heat transfer component 30 and the battery main body except the battery electrode in sequence from top to bottom.

### Embodiment 4

The present invention further provides a battery pack connecting assembly (not shown in the figures). The battery pack connecting assembly includes a support (not shown in the figures) and the electrical device assembly 102 as described in any of the preceding items. The object to be measured 50 is arranged on the support. The object to be measured 50 includes one or more bus-bars. The temperature measuring assembly 101 includes one or more temperature measuring elements 10, and the temperature measuring elements 10 are spaced apart from the bus-bars in a one-to-one correspondence manner. The output connector 20 is electrically connected with the one or more temperature measuring elements 10. The heat transfer component 30 is arranged to be in contact with the bus-bars, so that the bus-bars are in heat transfer connection with the corresponding temperature measuring elements 10.

It can be understood that the shape and structure of the support are selected according to application needs, and are suitable as long as it can bear the object to be measured 50.

Preferably, the output connector 20 includes a pair of electrically conductive layers 23. All the temperature measuring elements 10 are electrically connected with the pair of electrically conductive layers 23. It can be understood that “a pair” means two, used herein only for the purpose of illustration.

As another specific connection manner, the output connector 20 includes one or multiple pairs of electrically conductive layers 23. Each of the temperature measuring element 10 is electrically connected with a pair of electrically conductive layers 23 in a one-to-one correspondence manner. That is, the number of the electrically conductive layers 23 is selected according to that of the temperature measuring elements 10, so that each of the temperature measuring element 10 is connected with a pair of electrically conductive layers 23 in a one-to-one correspondence manner.

### Embodiment 5

The present invention further provides a vehicle battery pack (not shown in the figures). The vehicle battery pack includes a battery (not shown in the figures), a support and the electrical device assembly 102 as described in any of the preceding items. The electrical device assembly 102 is arranged on the support. The object to be measured 50 is a bus-bar, and is electrically connected with an electrode of the battery.

It can be understood that the battery is configured to provide power for a vehicle. The specific specification and parameters of the battery are selected according to needs.

The above descriptions are merely preferred embodiments of the present invention, and are not intended to limit the protection scope of the present invention. Any modifications, equivalents or improvements or the like fallen within the spirit of the present invention shall be encompassed within the scope of the claims of the present invention.

What is claimed is:

1. A temperature measuring assembly, comprising:
a temperature measuring element configured to measure temperature of an object to be measured and output a temperature signal, and be spaced apart from the object to be measured;
an output connector electrically connected with the temperature measuring element to receive the temperature signal; and
a heat transfer component configured to be in contact with the temperature measuring element, and used for contact with the object to be measured.

2. The temperature measuring assembly of claim 1, wherein the heat transfer component covers and encircles the temperature measuring element.

3. The temperature measuring assembly of claim 1, wherein the heat transfer component is thermo-sensitive adhesives.

4. The temperature measuring assembly of claim 1, wherein the heat transfer component is an integrated component made by curing melt silicone.

5. The temperature measuring assembly of claim 1, wherein the temperature measuring element is a thermistor.

6. The temperature measuring assembly of claim 5, wherein the temperature measuring element is a chip resistor.

7. The temperature measuring assembly of claim 5, wherein the temperature measuring element is a negative temperature coefficient thermistor.

8. The temperature measuring assembly of claim 1, wherein the output connector is a circuit board or a flexible flat cable.

9. The temperature measuring assembly of claim 8, wherein the circuit board is a flexible circuit board.

10. The temperature measuring assembly of claim 1, wherein
the output connector is provided with a first surface and a second surface;
the output connector is provided with a connecting through hole along the through-thickness direction, and the connecting through hole communicates one side of the first surface with one side of the second surface of the output connector;
the temperature measuring element is arranged on the first surface or the second surface of the output connector; the heat transfer component is configured to extend and protrude from the first surface of the output connector out of the second surface of the output connector via the connecting through hole.

11. The temperature measuring assembly of claim 10, wherein
the output connector is provided with two connecting through holes;
the heat transfer component extends and protrudes from the first surface of the output connector out of the second surface of the output connector via the two connecting through holes, and is connected with the output connector into a whole on one side of the second surface.

12. The temperature measuring assembly of claim 1, wherein
the output connector comprises an insulating layer and an electrically conductive layer; the insulating layer is configured to wrap around the electrically conductive layer;
a notch or a recess is formed on the upper surface of the insulating layer;
the electrically conductive layer extends to the recess or the notch;
the temperature measuring element is arranged at the recess or the notch, and is electrically connected with the electrically conductive layer.

13. The temperature measuring assembly of claim 12, wherein
the heat transfer component covers the temperature measuring element, and at least partially fills in the notch or the recess.

14. The temperature measuring assembly of claim 13, wherein
the output connector is provided with a first surface and a second surface;
the output connector is provided with a connecting through hole along the through-thickness direction, and the connecting through hole communicates one side of the first surface of the output connector with one side of the second surface;
the recess or the notch is communicated with the connecting through hole;
the temperature measuring element is arranged on the first surface or the second surface of the output connector;
the heat transfer component extends and protrudes from the first surface of the output connector out of the second surface of the output connector via the connecting through hole.

15. An electrical device assembly, comprising an object to be measured and the temperature measuring assembly claim 1, wherein
the object to be measured is arranged to be in contact with the heat transfer component, and is spaced apart from the temperature measuring element.

16. The electrical device assembly of claim 15, wherein
the output connector is provided with a connecting through hole along the through-thickness direction;
the output connector is arranged between the temperature measuring element and the object to be measured;
the heat transfer component achieves a heat transfer connection between the temperature measuring element and the object to be measured via the connecting through hole.

17. The electrical device assembly of claim 15, wherein
the output connector is provided with a first surface and a second surface;
the output connector is provided with a connecting through hole along the through-thickness direction, and the connecting through hole communicates one side of the first surface of the output connector with one side of the second surface;
the temperature measuring element is arranged on the first surface or the second surface of the output connector;
the heat transfer component extends and protrudes from the first surface of the output connector out of the second surface of the output connector via the connecting through hole.

18. The electrical device assembly of claim 17, wherein
the output connector comprises an insulating layer and an electrically conductive layer; the insulating layer is arranged to wrap around the electrically conductive layer;
a recess or a notch is formed in the first surface or the second surface of the insulating layer;
the electrically conductive layer extends to the recess or the notch;
the temperature measuring element is arranged at the recess or the notch, and is electrically connected with the electrically conductive layer.

19. The electrical device assembly of claim 18, wherein
the heat transfer component is provided with a limiting top;
the limiting top is configured to cover the temperature measuring element, and at least partially fill in the recess or the notch; and
the limiting top has a radial size greater than that of the connecting through hole.

20. The electrical device assembly of any of claim 16, wherein
the object to be measured is provided with a holding through hole or a holding groove along the through-thickness direction;
the holding through hole or the holding groove is arranged to communicate with the connecting through hole;
the heat transfer component extends to fill in the holding through hole or the holding groove.

21. The electrical device assembly of claim 20, wherein the heat transfer component is provided with a limiting bottom;
the limiting bottom extends and protrudes out of the holding through hole, and has a radial size greater than that of the holding through hole.

22. A battery pack connecting assembly, comprising a support and the electrical device assembly of any of claim 15, wherein
the object to be measured is arranged on the support;
the object to be measured comprises one or more bus-bars;
the temperature measuring assembly comprises one or more temperature measuring elements, and the temperature measuring elements are spaced apart from the bus-bars in a one-to-one correspondence manner;
the output connector is electrically connected with the one or more temperature measuring elements;
the heat transfer component is in contact with the bus-bars, so that the bus-bars are in heat transfer connection with the corresponding temperature measuring elements.

23. The battery pack connecting assembly of claim 22, wherein
the output connector comprises a pair of electrically conductive layers;
all the temperature measuring elements are electrically connected with the pair of electrically conductive layers.

24. The battery pack connecting assembly of claim 22, wherein
the output connector comprises one or multiple pairs of electrically conductive layers; and
each of the temperature measuring element is electrically connected with the pair of electrically conductive layers in a one-to-one correspondence manner.
